(19) United States
(12) Patent Application Publication
(10) Pub. No.: US 2024/0087992 A1
(43) Pub. Date: Mar. 14, 2024

(54) CHIP PACKAGE, CHIP SYSTEM, METHOD OF FORMING A CHIP PACKAGE, AND METHOD OF FORMING A CHIP SYSTEM

(71) Applicant: Infineon Technologies AG, Neubiberg (DE)

(72) Inventors: Ke Yan Tean, Melaka (MY); Edmund Sales Cabatbat, München (DE); Kean Ming Koe, Penang (MY)

(21) Appl. No.: 18/453,475

(22) Filed: Aug. 22, 2023

(30) Foreign Application Priority Data
Sep. 8, 2022 (DE) 102022122823.1

(51) Int. Cl. H01L 23/495; H01L 25/00; H01L 25/065

(52) U.S. Cl. CPC H01L 23/49524; H01L 23/49555; H01L 23/49575; H01L 25/0657; H01L 25/50; H01L 2225/06589

(57) ABSTRACT

A chip package is provided. The chip package includes a first chip, a second chip, an electrically conductive structure to which the first chip and the second chip are mounted, at least one contact terminal for electrically contacting the first chip and/or the second chip, and encapsulation material at least partially encapsulating the first chip, the second chip, and the electrically conductive structure. The encapsulation material forms a chip package body from which the at least one contact terminal protrudes. At least a portion of the electrically conductive structure forms a portion of an outer surface of the chip package body.

### TECHNICAL FIELD

Various embodiments relate generally to a chip package, a chip system, a method of forming a chip package, and to a method of forming a chip system.

### BACKGROUND

In a chip package, in particular in a power chip package, thermal management may be difficult. Specifically, it may be difficult to dissipate heat from a center of the chip package to an outside of the chip package.

### SUMMARY

A chip package is provided. The chip package may include a first chip, a second chip, an electrically conductive structure to which the first chip and the second chip are mounted, at least one contact terminal for electrically contacting the first chip and/or the second chip, and encapsulation material at least partially encapsulating the first chip, the second chip, and the electrically conductive structure, wherein the encapsulation material forms a chip package body from which the at least one contact terminal protrudes, wherein at least a portion of the electrically conductive structure forms a portion of an outer surface of the chip package body.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIGS. 1A and 1B show respective cross-sectional views of a chip package according to a prior art;

FIGS. 2A to 2D show respective schematic cross-sectional views of a chip package in accordance with various embodiments;

FIG. 3A shows a schematic top view of a chip package in accordance with various embodiments;

FIG. 3B shows a schematic cross-sectional view along a line A-A′ of the chip package of FIG. 3A;

FIGS. 4A and 4B show respective schematic cross-sectional views of a chip package in accordance with various embodiments;

FIG. 5 shows a schematic cross-sectional view of a chip system in accordance with various embodiments;

FIGS. 6 and 7 show respective flow diagrams of a method of forming a chip package in accordance with various embodiments; and

FIG. 8 shows a flow diagram of a method of forming a chip system in accordance with various embodiments.

### DETAILED DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

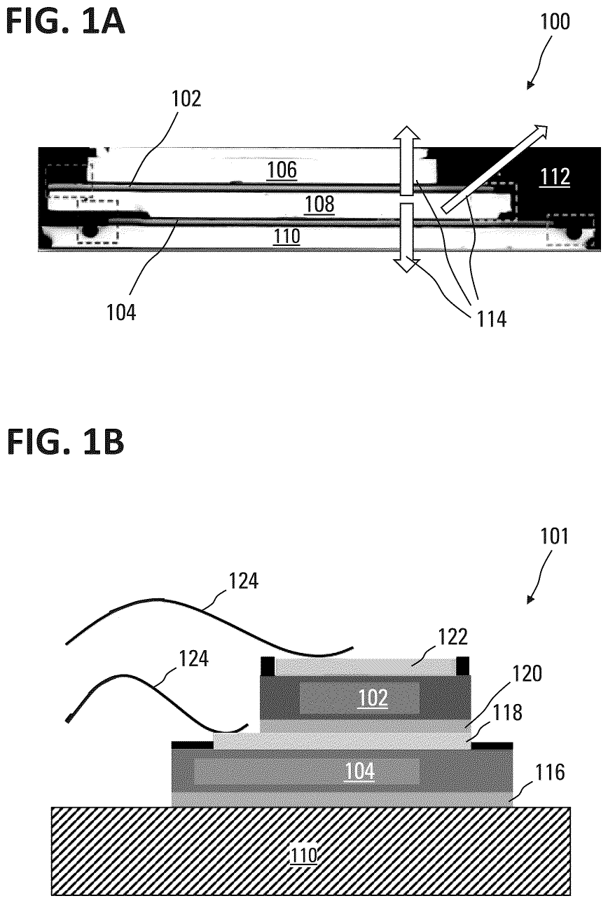

FIG. 1A shows a cross-sectional view of a chip package 100 of a prior art. The chip package 100 includes a first chip 102 and a second chip 104. The first chip 102 and the second chip 104 form a stack with the first chip 102 arranged as the top chip and the second chip 104 arranged as the bottom chip. Both chips 102, 104 are mounted to a central clip 108, the top chip 102 is further mounted to a top clip 106, and the bottom chip 104 is mounted to a leadframe 110. The central clip 108, the first chip 102 and the second chip 104 are completely embedded in encapsulation material 112 (also referred to as mold material or mold), and the leadframe 110 and the top clip 106 are partially embedded in the encapsulation material 112.

Heat generated or accumulated in a center of the chip package 100, for example in the central clip 108, the top chip 102, and/or the bottom chip 104, may be difficult to dissipate, because the heat may only be transferred indirectly from the central area of the chip package 100, e.g. from the central clip 108, to an outside of the chip package 100, e.g. air (also referred to as ambient).

As indicated by arrows 114 in FIG. 1A, current methods/paths to dissipate heat include a dissipation from the central clip 108 through the encapsulation material 112 to air, from the central clip 108 through the top chip 102 to air, and through the leadframe 110 to a bottom of the chip package 100.

FIG. 1B shows another chip package 101 in which a stack of two chips 102, 104 is formed by chip-on-chip diffusion soldering, using diffusion solder 120 for attaching the top chip 102 onto a front side metallization 118 of the bottom chip 104. Wire bonds 124 are attached to the front side metallization 118 of the bottom chip 104 and to a front side metallization 122 of the top chip 102. An encapsulation material that completely encapsulates the bottom chip 104, the top chip 102, and the wire bonds 124, is omitted in the figure, as well as a connection between the wire bonds 124 and a lead frame 110 on which the chip stack is mounted. Also in the chip package 101, a sufficient heat dissipation from both chips 102, 104 and/or from an interface between the two chips 102, 104 may be difficult to achieve because of the indirect heat transfer to an outside of the chip package 101, similar to what was described in context with FIG. 1A.

In various embodiments of a chip package, an electrically conductive structure to which two or more chips are mounted (e.g., a clip between the chips) may be exposed to ambient, e.g., to air, in order to have a better thermal dissipation than, e.g., the wire bond chip package 101 of FIG. 1B, and/or than the chip package 100 of FIG. 1A.

In various embodiments, the chip package may have a stepped contour with exposed thermally conductive structures at at least two levels of the stepped chip package, for example at a top level and at a middle level, wherein the at least one middle level may additionally dissipate heat from a center of the chip package. Optionally, at a bottom level, a further thermally conductive cooling structure may be exposed.

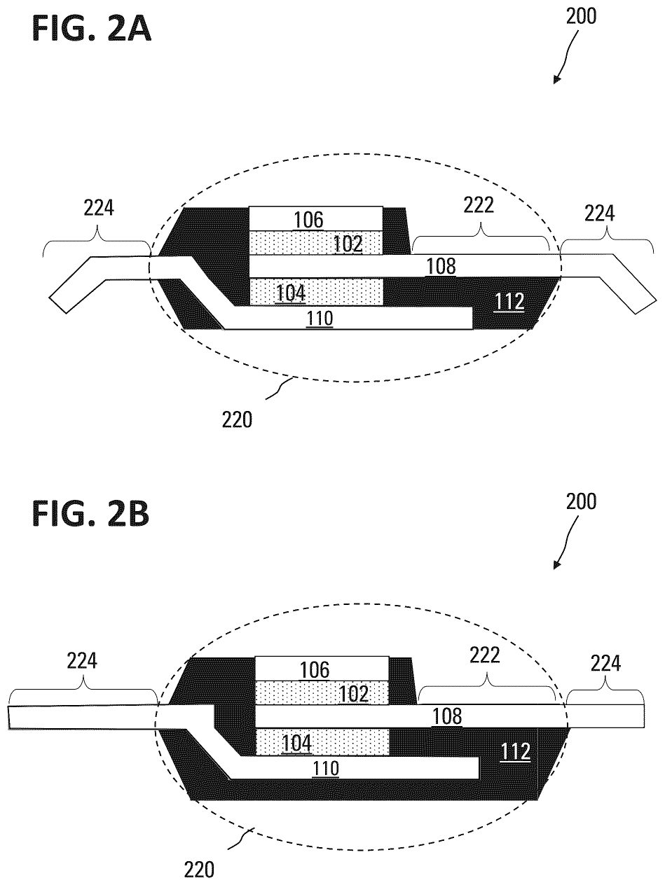

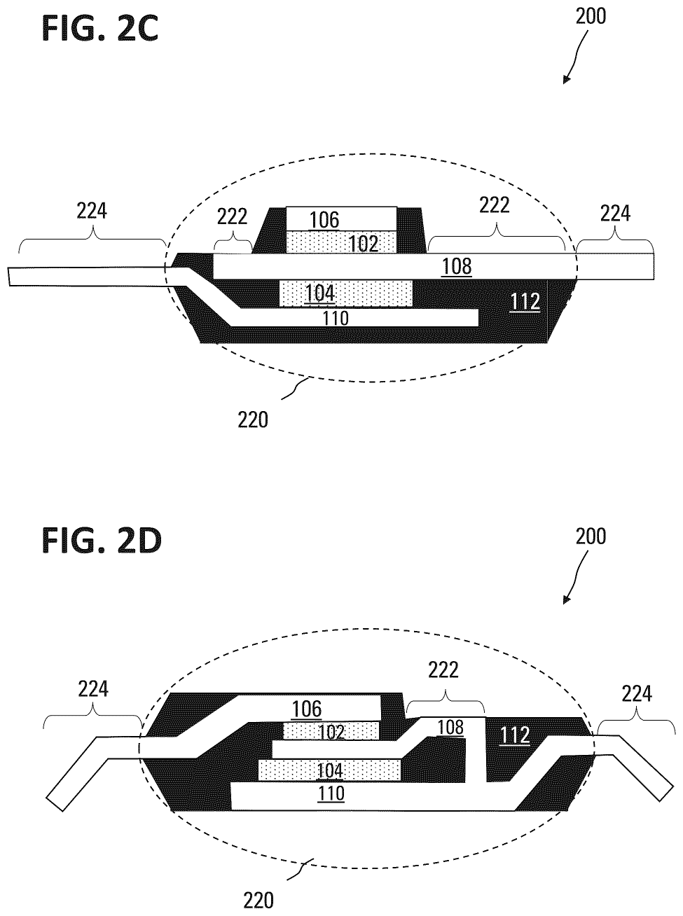

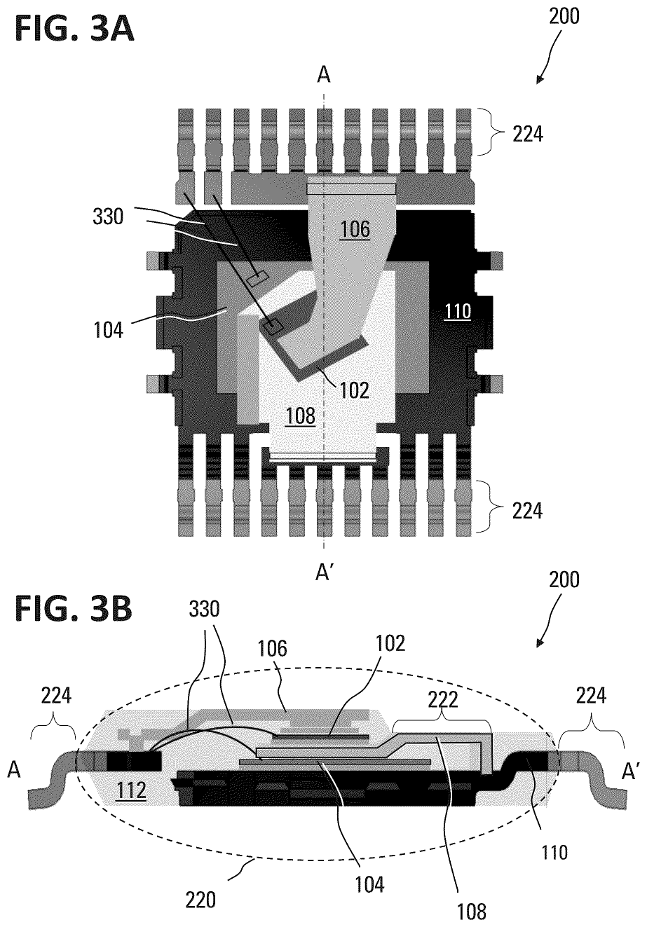

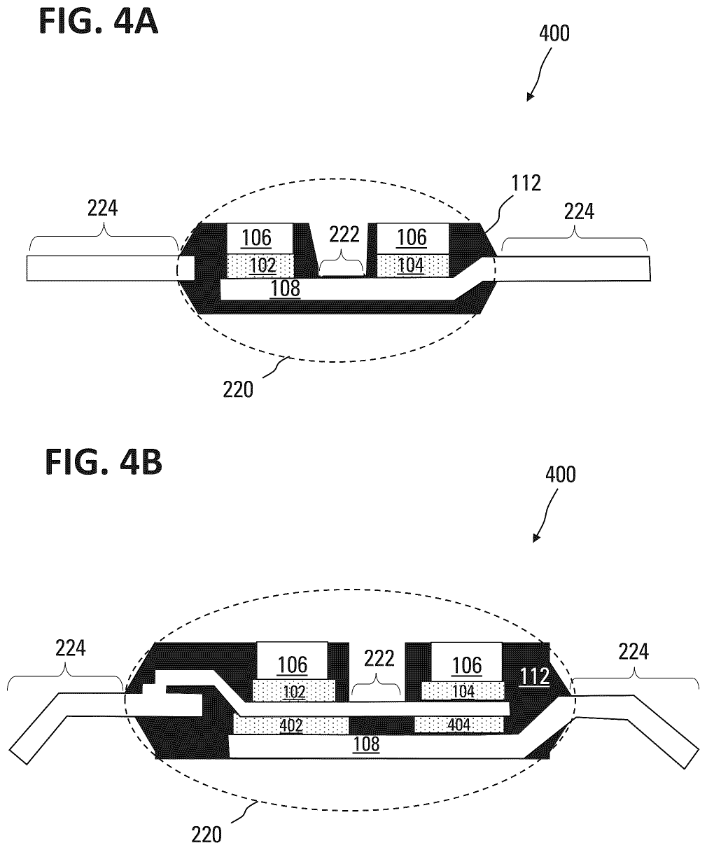

Each of FIGS. 2A to 2D shows a schematic cross-sectional view of a chip package 200 in accordance with various embodiments, FIG. 3A shows a schematic top view of a chip package 200 in accordance with various embodiments, FIG. 3B shows a schematic cross-sectional view along a line A-A′ of the chip package 200 of FIG. 3A, and each of FIGS. 4A and 4B shows a schematic cross-sectional view of a chip package 400 in accordance with various embodiments.

The chip package 200, 400 may include a first chip 102 and a second chip 104. Optionally, the chip package 200, 400 may include further chips, for example a third chip 402, a fourth chip 404, etc. The chips 102, 104 may for example include or consist of electronic circuit elements or electronic circuits, for example diodes, transistors, e.g. IGBT or MOSFETs, e.g. power chips, which may be configured to form integrated multi-chip circuit elements, like for example a power factor correction element, a half-bridge, etc. As an example, the first chip 102 may be an IGBT, and the second chip 104 may be a diode, and both may be configured to form, in combination, an integrated power factor correction product.

The chip package 200, 400 may further include an electrically conductive structure 108 to which the first chip 102 and the second chip 104 are mounted. The electrically conductive structure 108 may for example be a conductive clip or plate. The electrically conductive structure 108 may in various embodiments be laterally extended in two dimensions (as opposed to a wire that is extended essentially in one dimension only), e.g., as a layer or a plate, for example as a clip. A material of the electrically conductive structure 108 may for example include or consist of copper, e.g. plated copper or copper alloy, or any other material known in the art to be suitable for forming the electrically conductive structure 108. The first chip 102 and the second chip 104 may for example be mounted to the electrically conductive structure 108 by contact pads formed on the respective chip surface, e.g. by a solder, an electrically conductive glue, or any other suitable method known in the art.

The chip package 200, 400 may further include at least one contact terminal 224 for electrically contacting the first chip 102 and/or the second chip 104. In each of FIGS. 2A to 2C, the contact terminal 224 shown on the left-hand side is configured to electrically contact the second (bottom) chip 104 at its bottom side, and that contact terminal 224 may for example be part of an electrical contact structure 110, e.g., of a leadframe. The contact terminal 224 shown on the right-hand side of FIGS. 2A to 2C may be part of the electrically conductive structure 108. The electrical configurations shown in FIG. 2A to 2C are merely for illustration and not intended to be limiting on this disclosure. In other embodiments such as FIG. 2D, the contact terminal 224 shown on the left hand side may form part of a clip 106 configured to electrically contact the top side of the first chip 102. On the other hand, the contact terminal 224 shown on the right-hand side of FIG. 2D forms part of a lead frame 110 that is in electrical contact with the bottom side of the second chip 104. The conductive structure 108 is bent to provide for both an exposed portion 222 and connection with the lead frame 110.

The chip package 200, 400 may further include encapsulation material 112 at least partially encapsulating the first chip 102, the second chip 104 (and optional further chips), and the electrically conductive structure 108. The encapsulation material 112 may form a chip package body 220 from which the at least one contact terminal 224 may protrude. The encapsulation material 112 may include or consist of an electrically isolating material as known in the art, for example a mold material, e.g. a polymer material. The encapsulation material 112 may have a lower thermal conductivity than the electrically conductive structure 108.

At least a portion of the electrically conductive structure 108 may form a portion 222 of an outer surface of the chip package body 220. As another way to phrase it, a portion of the contour of the chip package body 220 may be formed by the exposed portion 222 of the electrically conductive structure 108.

In various embodiments, such as that illustrated in FIG. 2B, the electrically conductive structure 108 may include at least one portion 222 that is exposed to ambient on a first side and covered by the encapsulation material 112 on a second side opposite the first side.

The first chip 102 and the second chip 104 may be mounted on opposite sides of the electrically conductive structure 108, for example forming a stack. The exemplary embodiments of FIG. 2A to 2C and of FIGS. 3A and 3B illustrate such a configuration of a chip package 200. FIGS. 2A and 2D illustrate a double-sided cooling chip package arrangement where a surface of both the top clip 106 and leadframe 110 are exposed to the ambient.

In various embodiments, for example when the first chip 102 and the second chip 104 are mounted on opposite sides of the electrically conductive structure 108 (but optionally in addition in the side-by-side configuration described below), the portion 222 of the electrically conductive structure may be laterally arranged between the first chip 102 and a circumference of the chip package 200, 400, and/or between the second chip 104 and the circumference of the chip package 200, 400. For example, the portion 222 may, in a top view, be laterally arranged with respect to one or both of the chips 102, 104. In FIG. 3A, the encapsulation material 112 is omitted to show relative positions of the chips 102, 104, the electrically conductive structure 108, a top contact structure 106 (e.g., a top clip), etc., but in combination with the cross-sectional view of FIG. 3B, which includes the encapsulation material 112, the arrangement of the portion 222 laterally displaced from the first chip 102 (and partially overlapping the second chip 104) in the top view is clear.

In various embodiments, the portion 222 may be arranged on more than one side of the first chip 102 and/or of the second chip 104 in a lateral sense. A respective exemplary embodiment is shown in FIG. 2C, in which the portion 222 is arranged on two opposite sides of the first chip 102 and of the second chip 104 in a lateral sense.

A similar arrangement may in various embodiments be suitable for a chip package 200 that may include more than two chips. In a stacked configuration that has a third chip sandwiched between the first chip 102 and the second chip 104, the electrically conductive structure 108 may for example be arranged between the first chip 102 and the middle chip, and may be exposed on one lateral side of the first chip 102, and a further electrically conductive structure may for example be arranged between the second chip 104 and the third chip, and may have its exposed portion 222 on another, e.g. opposite, lateral side of the first chip 102.

In various embodiments, such as FIGS. 4A and 4B, the first chip 102 and the second chip 104 may be mounted on the same side of the electrically conductive structure 108. The exemplary embodiment of the chip package 400 of FIG. 4A illustrates such a configuration. The portion 222 of the electrically conductive structure 108 may in such a case be laterally arranged between the first chip 102 and the second chip 104. For chip packages comprising more than two chips, the chips may be arranged as a line, in a matrix configuration, or any other suitable configuration, and the portion 222 may be arranged, as a single portion or multiple sub-portions, between respective chip pairs.

In various embodiments, the stacked configuration and the side-by-side-configuration may be combined, with the first chip and the second chip arranged on the first side of the electrically conductive structure 108, with the portion between them, and at least one further chip arranged on the opposite side of the electrically conductive structure 108, and a further portion between at least one of the chips and a lateral circumference of the chip package body 222, or, as another way to phrase it, laterally displaced from at least one of the chips (e.g., the top chip 102) in a top view. An exemplary embodiment with a double sided cooling arrangement is illustrated in FIG. 4B. In this example, the first chip 102 and the second chip 104 mounted on a top side of the electrically conductive structure 108 are connected to exposed top clips 106, while the third chip 402 and the fourth chip 404 mounted on a lower opposed side of the electrically conductive structure 108 are connected to a lead frame with an exposed heat dissipation surface.

Both embodiments, the stacked configuration and the side-by-side-configuration, may provide a chip package 200, 400 with a stepped contour, in other words, with an additional step as compared to a chip package 100, 101 of the prior art. At the stepped level, the portion 222 may be exposed as an additional cooling surface.

The chip packages 200, 400 of various embodiments may have an increased cooling efficiency.

This may be illustrated by a comparison of the prior art chip package 100 of FIG. 1A and the chip package 200 of FIGS. 3A and 3B in their cooling efficiency with respect to heat generated in the first (top) chip 102: Both chip packages 100, 200 may include a top clip 106 as a cooling path. Heat may thus in both cases be transferred from the first chip 102 to the top clip 106 to ambient. However, the cooling path through the bottom of the first chip 102 differs in the two cases: Whereas, in the prior art chip package 100, a main cooling path may be from the first chip 102 to the middle clip 108 to the second (bottom) chip 104 to the leadframe 110 to ambient, the chip package 200 of various embodiments offers an additional cooling path from the first chip 102 to the middle clip 108 to ambient. The considerably shorter thermal path in the chip package 200 increases the cooling efficiency. Similar consideration apply to the chip package 400 and further embodiments.

In various embodiments, the portion 222 may be configured to be directly contacted by a cooling fluid, e.g. air or a liquid, e.g. water.

In various embodiments, a chip system 500 may be formed.

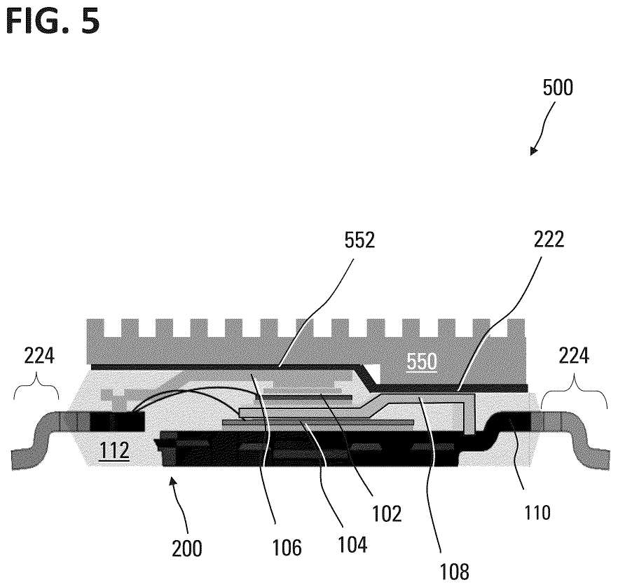

FIG. 5 shows a schematic cross-sectional view of a chip system 500 in accordance with various embodiments.

The chip system 500 may include a chip package 200, 400 in accordance with any of the embodiments described above (in FIG. 5, a chip package 200 is used), and a heat sink 550 thermally contacting the portion 222 of the electrically conductive structure 108.

The heat sink 550 may be configured and attached essentially as known in the art. For example, the heat sink 550 may have a high thermal conductivity (e.g., higher than the thermal conductivity of the encapsulation material 112, and optionally higher than the electrically conductive structure 108), and/or the heat sink 550 may have a high ration of surface to volume, for example by including fins or similar structures. The heat sink 550 may be attached to the portion 222 for example using a thermal interface material 552. The heat sink 550 may be configured to be exposed to ambient, e.g. to be contacted by a cooling fluid, e.g. air or a liquid.

The chip package 200, 400 may include further cooling structures that may be exposed at outer regions of the chip package body 222, for example at a top of the chip package 200, 400 (see for example FIGS. 2A to 2D, 3A to 3B, and 4A to 4B, in which a top clip 106 is exposed) and/or at a bottom of the chip package 200, 400 (see for example FIGS. 2A, 2D, 3A and 3B, where a leadframe 110 is exposed at the bottom of the chip package 200).

In a case where two or more steps of the chip package 200, 400 include cooling surfaces, the heat sink 550 of the chip system 500 may be configured as a stepped heat sink 550 (see FIG. 5), or for example as a two-part heat sink 550.

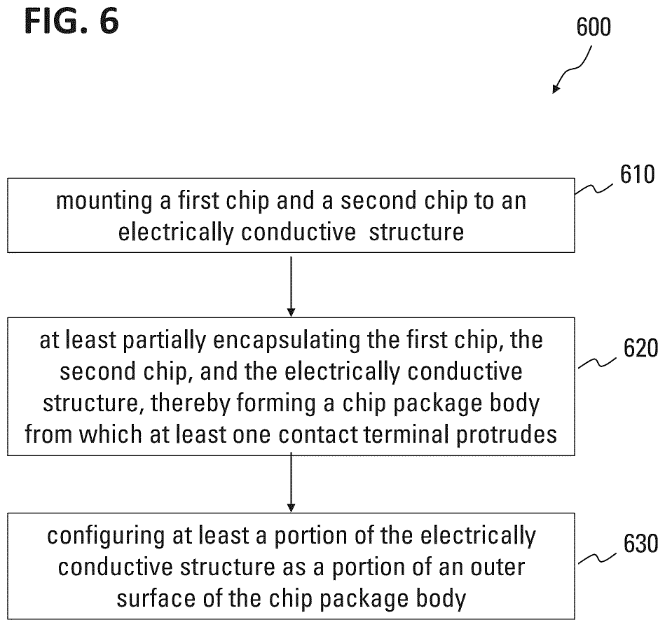

FIG. 6 shows a flow diagram 600 of a method of forming a chip package in accordance with various embodiments.

The method may include mounting a first chip and a second chip to an electrically conductive structure (in 610), at least partially encapsulating the first chip, the second chip, and the electrically conductive structure, thereby forming a chip package body from which at least one contact terminal protrudes (in 620), and configuring at least a portion of the electrically conductive structure as a portion of an outer surface of the chip package body (in 630).

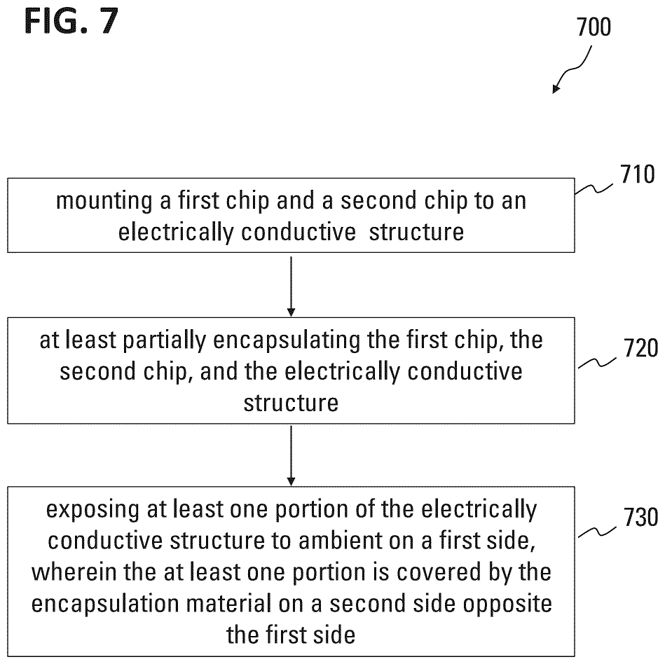

FIG. 7 shows a flow diagram 700 of a method of forming a chip package in accordance with various embodiments.

The method may include mounting a first chip and a second chip to an electrically conductive structure (in 710), at least partially encapsulating the first chip, the second chip, and the electrically conductive structure (in 720), and exposing at least one portion of the electrically conductive structure to ambient on a first side, wherein the at least one portion is covered by the encapsulation material on a second side opposite the first side (in 730).

While most of the chip processing and packaging may be configured as normal frontend- and backend processes, in other words, allowing to use established processes, the portion 222 of the electrically conductive structure 108 may be left exposed by methods such as film assist molding processes. In other words, a specifically shaped cavity may be used for selectively encapsulating the arrangement including the electrically conductive structure 108, the first chip 102, and the second chip 104. A film arranged in contact with the portion 222 (e.g., as film assisted molding) prevents said portion from being encapsulated during the molding process. In other embodiments, the entire electrically conductive structure 108 may be encapsulated by a molding process, with some encapsulation material 112 subsequently being removed (for example by laser ablation) so as to expose the portion 222 of the electrically conductive structure 108.

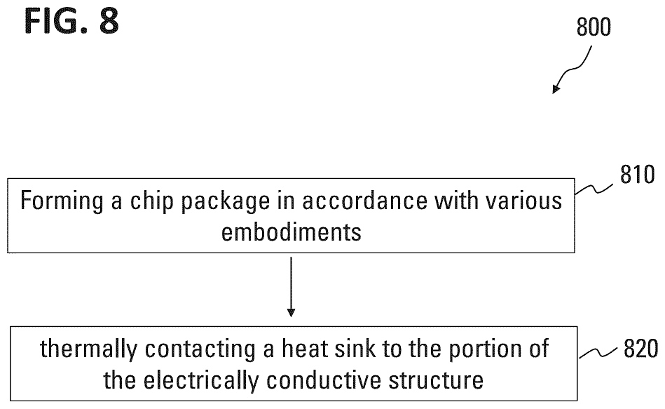

FIG. 8 shows a flow diagram 800 of a method of forming a chip system in accordance with various embodiments.

The method may include forming a chip package in accordance with the embodiments described above (in 810), and thermally contacting a heat sink to the portion of the electrically conductive structure (in 820).

The forming the chip package may in various embodiments include mounting a first chip and a second chip to an electrically conductive structure, at least partially encapsulating the first chip, the second chip, and the electrically conductive structure, thereby forming a chip package body from which at least one contact terminal protrudes, and configuring at least a portion of the electrically conductive structure as a portion of an outer surface of the chip package body.

The forming the chip package may in various embodiments include mounting a first chip and a second chip to an electrically conductive structure, at least partially encapsulating the first chip, the second chip, and the electrically conductive structure, and exposing at least one portion of the electrically conductive structure to ambient on a first side, wherein the at least one portion is covered by the encapsulation material on a second side opposite the first side.

The thermally contacting the heat sink to the portion may for example include arranging a thermal interface material on the portion and arranging the heat sink in contact with the thermal interface material, e.g. pressing the heat sink onto the thermal interface material.

Various examples will be illustrated in the following:

Example 1 is a chip package. The chip package may include a first chip, a second chip, an electrically conductive structure to which the first chip and the second chip are mounted, at least one contact terminal for electrically contacting the first chip and/or the second chip, and encapsulation material at least partially encapsulating the first chip, the second chip, and the electrically conductive structure, wherein the encapsulation material forms a chip package body from which the at least one contact terminal protrudes, wherein at least a portion of the electrically conductive structure forms a portion of an outer surface of the chip package body.

In Example 2, the subject-matter of Example 1 may optionally include that the at least one portion is exposed to ambient (or configured to be contacted by a heat sink).

In Example 3, the subject-matter of Example 1 or 2 may optionally include that the electrically conductive structure further includes a second portion covered by the encapsulation material.

In Example 4, the subject-matter of any of Examples 1 to 3 may optionally include that the first chip and the second chip are mounted on opposite sides of the electrically conductive structure.

In Example 5, the subject-matter of Example 4 may optionally include that the first chip and the second chip form a stack.

In Example 6, the subject-matter of any of Examples 1 to 5 may optionally include that the portion of the electrically conductive structure is laterally arranged between the first chip and a circumference of the chip package and/or between the second chip and the circumference of the chip package.

In Example 7, the subject-matter of Example 1 or 2 may optionally include that the first chip and the second chip are mounted on the same side of the electrically conductive structure.

In Example 8, the subject-matter of any of Examples 1 to 3 may optionally include that the portion of the electrically conductive structure is laterally arranged between the first chip and the second chip.

In Example 9, the subject-matter of any of Examples 1 to 8 may optionally include that the electrically conductive structure is a clip.

In Example 10, the subject-matter of any of Examples 1 to 9 may optionally further include a second electrically conductive structure attached to the first chip opposite the electrically conductive structure.

In Example 11, the subject-matter of Example 10 may optionally include that a side of the second electrically conductive structure opposite the first chip is exposed to ambient.

In Example 12, the subject-matter of Example 10 or 11 may optionally include that the second electrically conductive structure is a clip or a lead frame.

In Example 13, the subject-matter of any of Examples 10 to 12 may optionally further include a third electrically conductive structure attached to the second chip opposite to the electrically conductive structure, wherein a side of the third electrically conductive structure opposite the second chip is exposed to ambient.

In Example 14, the subject-matter of any of Examples 1 to 13 may optionally include that the first chip and/or the second chip are power chips.

Example 15 is a chip system. The chip system may include a chip package of any of Examples 1 to 14, and a heat sink thermally contacting the portion of the electrically conductive structure.

Example 16 is a method of forming a chip package. The method may include mounting a first chip and a second chip to an electrically conductive structure, at least partially encapsulating the first chip, the second chip, and the electrically conductive structure, thereby forming a chip package body from which at least one contact terminal protrudes, and configuring at least a portion of the electrically conductive structure as a portion of an outer surface of the chip package body.

In Example 17, the subject matter of Example 16 may optionally further include that the configuring at least a portion of the electrically conductive structure as a portion of an outer surface of the chip package body includes exposing at least one portion of the electrically conductive structure to ambient.

In Example 18, the subject-matter of Example 16 or 17 may optionally include that the electrically conductive structure further includes a second portion covered by the encapsulation material

In Example 19, the subject-matter of any of Examples 16 to 18 may optionally include that the first chip and the second chip are mounted on opposite sides of the electrically conductive structure.

In Example 20, the subject-matter of Example 19 may optionally include that the first chip and the second chip form a stack.

In Example 21, the subject-matter of any of Examples 16 to 20 may optionally include that the portion of the electrically conductive structure is laterally arranged between the first chip and a circumference of the chip package and/or between the second chip and the circumference of the chip package.

In Example 22, the subject-matter of Example 16 to 18 may optionally include that the first chip and the second chip are mounted on the same side of the electrically conductive structure.

In Example 23, the subject-matter of Example 22 may optionally include that the portion of the electrically conductive structure is laterally arranged between the first chip and the second chip.

In Example 24, the subject-matter of Example 16 may optionally include that the configuring the at least a portion of the electrically conductive structure as a portion of an outer surface of the chip package body includes exposing the portion by a grinding process and/or by a laser ablation process.

In Example 25, the subject-matter of Example 17 may optionally include that the exposing the at least one portion of the electrically conductive structure to ambient includes exposing the portion by a grinding process and/or by a laser ablation process.

In Example 26, the subject-matter of any of Examples 16 to 25 may optionally include that electrically conductive structure is a clip.

In Example 27, the subject-matter of any of Examples 16 to 26 may optionally further include attaching a second electrically conductive structure to the first chip opposite the electrically conductive structure.

In Example 28, the subject-matter of Example 27 may optionally further include exposing a side of the second electrically conductive structure opposite the first chip to ambient.

In Example 29, the subject-matter of Example 27 or 28 may optionally include that the second electrically conductive structure is a clip or a lead frame.

In Example 30, the subject-matter of any of Examples 27 to 29 may optionally further include attaching a third electrically conductive structure to the second chip opposite to the electrically conductive structure, and exposing a side of the third electrically conductive structure opposite the second chip sed to ambient.

In Example 31, the subject-matter of any of Examples 16 to 30 may optionally include that the first chip and/or the second chip are power chips.

Example 32 is a method of forming a chip system. The method may include forming a chip package in accordance with any of Examples 16 to 31, and thermally contacting a heat sink to the portion of the electrically conductive structure.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A chip package, comprising:
a first chip;
a second chip;
an electrically conductive structure to which the first chip and the second chip are mounted;
at least one contact terminal for electrically contacting the first chip and/or the second chip; and
encapsulation material at least partially encapsulating the first chip, the second chip, and the electrically conductive structure,
wherein the encapsulation material forms a chip package body from which the at least one contact terminal protrudes,
wherein at least a portion of the electrically conductive structure forms a portion of an outer surface of the chip package body.

2. The chip package of claim 1, wherein the portion of the electrically conductive structure is exposed to ambient.

3. The chip package of claim 1, wherein the electrically conductive structure further comprises a second portion covered by the encapsulation material.

4. The chip package of claim 1, wherein the first chip and the second chip are mounted on opposite sides of the electrically conductive structure.

5. The chip package of claim 4, wherein the first chip and the second chip form a stack.

6. The chip package of claim 1, wherein the portion of the electrically conductive structure is laterally arranged between the first chip and a circumference of the chip package and/or between the second chip and the circumference of the chip package.

7. The chip package of claim 1, wherein the first chip and the second chip are mounted on a same side of the electrically conductive structure.

8. The chip package of claim 7, wherein the portion of the electrically conductive structure is laterally arranged between the first chip and the second chip.

9. The chip package of claim 1, wherein the electrically conductive structure is a clip.

10. The chip package of claim 1, further comprising:
a second electrically conductive structure attached to the first chip opposite the electrically conductive structure.

11. The chip package of claim 10, wherein a side of the second electrically conductive structure opposite the first chip is exposed to ambient.

12. The chip package of claim 10, wherein the second electrically conductive structure is a clip or a lead frame.

13. The chip package of claim 10, further comprising:
a third electrically conductive structure attached to the second chip opposite to the electrically conductive structure,
wherein a side of the third electrically conductive structure opposite the second chip is exposed to ambient.

14. The chip package of claim 1, wherein the first chip and/or the second chip are power chips.

15. A chip system, comprising:
the chip package of claim 1; and
a heat sink thermally contacting the portion of the electrically conductive structure.

16. A method of forming a chip package, the method comprising:
mounting a first chip and a second chip to an electrically conductive structure;
at least partially encapsulating the first chip, the second chip, and the electrically conductive structure to form a chip package body from which at least one contact terminal protrudes; and
configuring at least a portion of the electrically conductive structure as a portion of an outer surface of the chip package body.

17. The method of claim 16, wherein the configuring comprises exposing the at least one portion to ambient.

18. The method of claim 17, wherein the exposing comprises exposing the portion by a grinding process and/or by a laser ablation process.

19. The method of claim 16, wherein the electrically conductive structure further comprises a second portion covered by the encapsulation material.

20. The method of claim 16, wherein the first chip and the second chip are mounted on opposite sides of the electrically conductive structure.

21. The method of claim 20, wherein the first chip and the second chip form a stack.

22. The method of claim 16, wherein the portion of the electrically conductive structure is laterally arranged between the first chip and a circumference of the chip package and/or between the second chip and the circumference of the chip package.

23. The method of claim 16, wherein the first chip and the second chip are mounted on a same side of the electrically conductive structure.

24. The method of claim 23, wherein the portion of the electrically conductive structure is laterally arranged between the first chip and the second chip.

25. The method of claim 16, wherein the configuring comprises exposing the portion by a grinding process and/or by a laser ablation process.

26. The method of claim 16, wherein electrically conductive structure is a clip.

27. The method of claim 16, further comprising:
attaching a second electrically conductive structure to the first chip opposite the electrically conductive structure.

28. The method of claim 27, further comprising:
exposing a side of the second electrically conductive structure opposite the first chip to ambient.

29. The method of claim 27, wherein the second electrically conductive structure is a clip or a lead frame.

30. The method of claim 27, further comprising:
attaching a third electrically conductive structure to the second chip opposite to the electrically conductive structure; and
exposing a side of the third electrically conductive structure opposite the second chip sed to ambient.

31. The method of claim 16, wherein the first chip and/or the second chip are power chips.

32. A method of forming a chip system, the method comprising:
mounting a first chip and a second chip to an electrically conductive structure;
at least partially encapsulating the first chip, the second chip, and the electrically conductive structure to form a chip package body from which at least one contact terminal protrudes;
configuring at least a portion of the electrically conductive structure as a portion of an outer surface of the chip package body; and
thermally contacting a heat sink to the portion of the electrically conductive structure.
